(19) United States
(12) Patent Application Publication
(10) Pub. No.: US 2025/0384171 A1
(43) Pub. Date: Dec. 18, 2025

(54) PROPERTY SKETCHING METHOD AND TOOLS

(71) Applicant: CoreLogic Solutions, LLC, Irvine, CA (US)

(72) Inventors: Ting Cheung, Flushing, NY (US); Christopher Fletcher, Edmond, OK (US); Chad Williamson, Oklahoma City, OK (US); Joseph Ellis, Yukon, OK (US)

(21) Appl. No.: 19/228,314

(22) Filed: Jun. 4, 2025

Related U.S. Application Data
(60) Provisional application No. 63/660,166, filed on Jun. 14, 2024.

(51) Int. Cl. G06F 30/12; G01S 17/89; G06F 30/13; H04W 4/029

(52) U.S. Cl. CPC G06F 30/12; G01S 17/89; G06F 30/13; H04W 4/029

(57) ABSTRACT

A method, system, and device for sketching a property are provided. The method may include presenting a video image of a property, enabling a selection of a plurality of features of interest associated with the property such as for example property exterior corners, interior corners, or interior walls via a user interface, tracking a motion of the communication device as the communication device travels between adjacent features of interest in the plurality of features of interest, and recording a location associated with each of the plurality of features of interest upon receiving the selection of each of the plurality of features of interest. The method may also include generating a first instance of a sketch of the property and providing the first instance of the sketch of the property to post-processing functionality that normalizes anomalies and/or reconciles features in the first instance of the sketch of the property.

### CROSS-REFERENCE TO RELATED APPLICATIONS

This application claims the benefit of priority under 35 U.S.C. § 119(e) to U.S. Provisional Patent Application No. 63/660,166, filed on Jun. 14, 2024, and entitled “PROPERTY SKETCHING METHOD AND TOOLS”. The entire disclosure of U.S. Provisional Patent Application No. 63/660,166 is incorporated herein by reference.

### FIELD OF THE DISCLOSURE

Embodiments of the present disclosure relate to automated and semi-automated property scanning and sketching tools.

### BACKGROUND

Real estate property valuation often requires the creation of a property sketches while the estimator or appraiser is physically on the property. The accurate creation of a property sketch with size and dimensional calculations correlates directly to an accurate property valuation. Said another way, the inaccurate creation of a property sketch can result in an inaccurate property valuation. This may have potential adverse impacts on future decisions made with respect to the property, such as being able to buy, sell, or secure a mortgage for the property.

There are a number of property-scanning and sketching tools available on the market. A majority of the existing property-scanning and sketching tools require the user to do a full scan of the property from the interior. The tool then attempts to account for wall thickness in an effort to extrapolate property size and dimensions. Existing interior scanning and sketching tools tend to be slower and unacceptably inaccurate. Existing interior scanning and sketching tools also require very detailed scanning and/or videos of every room in the property, which can present an uncomfortable privacy issue for homeowners.

### SUMMARY

Embodiments of the present disclosure contemplate an improved property scanning and sketching tool and method. In particular, embodiments described herein provide the ability to scan the exterior corners of a property, or an individual spot on each of the interior perimeter walls, or the interior corners of the property, to generate a sketch of the exterior perimeter and outline of the property with its calculated size and dimensions on the user's mobile device using plane detection and tracking. As a non-limiting example, a user carries a mobile device having appropriate cameras and/or sensors provided thereon. While the user walks around the exterior or interior of the property perimeter with the mobile device, the user marks the required features of interest (e.g., exterior or interior corners or interior walls).

In some embodiments, the feature marking may be facilitated with the use of Light Detection and Ranging (LiDAR) sensors and accompanying processors. For instance, LiDAR may be used to estimate a location of a feature of interest in space. When a user selects the feature of interest, the location of the feature in space is recorded with an appropriate feature recording function. The user may then walk with the mobile device to a next feature of interest (e.g., a next corner or wall) and repeat the process of marking the feature of interest. Successive features of interest may be marked and their corresponding locations may be recorded until all of the features of interest are marked and locations associated therewith are recorded. As a non-limiting example, once all corners or walls (e.g., exterior corners or interior perimeter walls or interior corners) of the property have been marked, the locations of each feature may be provided to a site sketching function that lays out all the locations in a common coordinate system and then draws an instant perimeter sketch of the property with size and dimensions associated therewith.

In some embodiments, a communication device, such as a mobile device, is contemplated to include an application that leverages LiDAR and/or photogrammetry to determine an intersection of wall planes, which may be referred to herein as corners and/or features of interest. While using the application, the user is presented with these intersection points to choose, thereby facilitating the creation of interior or exterior diagrams that depict whole or partial architectural features of residential or commercial structures. As the user traverses around the structure, the distance traveled is captured by an Inertial Measurement Unit (IMU) of the mobile device. Location and distance traveled between points may use any combination of the IMU, compass, and Global Positioning Systems (GPS) provided natively on the mobile device.

After point collection and determination by the end user, the points are provided to a sketching function, which generates a first instance of the property sketch. The first instance of the sketch and the corresponding locations of the features of interest are then passed to a post-processing function. The post-processing function may be configured to correct and normalize anomalies that arise from the slight inaccuracies of the IMU and compass on the mobile device. For instance, the post-processing function may be configured to normalize walls to segmented degree increments within a set tolerance (e.g., to a tolerance of less than 1 degree or 0 degrees). For instance, if a wall exists at 96 degrees relative to the world of 0 degrees, the wall is normalized by the post-processing function to 90 degrees and the connecting adjacent walls are consecutively adjusted (e.g., healed) to maintain property connections. In some embodiments, walls are processed in the order that the user captured them.

During post-processing, precedence may be given to preserving captured wall length, due to the length having far better accuracy to the wall angle. As each wall is processed according to world angle normalization, subsequent walls are adjusted by the same angle, rotated around the starting point of the wall being processed.

After wall angle normalization, walls can be analyzed for any walls that exist on the same axis that are nearly coplanar within a set threshold. If walls are found to be co-planar or substantially co-planar (e.g., co-planar within the set threshold), the substantially co-planar walls are each moved to their average position on the axis perpendicular to their long/running axis.

After coplanar threshold processing, the post-processing function may further search for known features that need to be made symmetrical, such as bay windows, doors, and point bay windows. The post-processing function may attempt to recreate such features as symmetrical by averaging and centering with the data provided. For example, when a bay window is detected, the following actions can be taken:
(i) the middle wall is centered within the detected opening on a parent wall;
(ii) the angled sides are made symmetrical in length and angle;
(iii) the parent wall connections are forced coplanar if both in parallel axis with bay window; and
(iv) the parent wall connections and their adjacent connections are healed.

Point bay windows and/or doors can be processed in a similar way to bay windows.

The sketching tools and methods provided herein are capable of creating an accurate property sketch faster and with a higher level of accuracy than tools that require full interior scanning. Other advantages offered by the tools and methods described herein include: (1) more accurate development of an exterior property geometry due to direct measurement of features; (2) faster data capture process facilitated by allowing the user to walk the property rather than also requiring the user to capture a complete video of the entire property; and (3) less invasive capture process that helps preserve a property owner's privacy by allowing the scanning of exterior features rather than the scanning of interior features of the property.

According to at least some embodiments of the present disclosure, a method and/or tool are provided that enable a user to create a complete or partial architectural sketch of a scanned structure (e.g., property, building, etc.). The mobile device disclosed herein may utilize LiDAR, IMUs, and/or a compass to help the user locate corners and edges of structures to capture the shape and design. The coordinates provided establish wall length and position in the world. The lengths between points are considered accurate and priority is given to preserving the length and normalizing angles. The result is a complete or partial architectural sketch of the structure scanned.

Embodiments of the present disclosure contemplate systems, methods, and devices for use in facilitating automated or semi-automated property scanning and sketching. In some embodiments, a method for sketching a property is provided that includes: presenting, via a user interface of a communication device, a video image of a property; enabling a selection of a plurality of features of interest associated with the property via the user interface; tracking a motion of the communication device as the communication device travels between adjacent features of interest in the plurality of features of interest; recording a location associated with each of the plurality of features of interest upon receiving the selection of each of the plurality of features of interest; determining a distance between at least two features of interest in the plurality of features of interest based on the motion of the communication device; and based on the location associated with each of the plurality of features of interest and based on the distance between the at least two features of interest, generating a first instance of a sketch of the property.

According to at least some aspects, the method may further include providing the first instance of the sketch of the property to post-processing functionality that normalizes anomalies and/or reconciles features in the first instance of the sketch of the property; receiving, from the post-processing functionality, a second instance of the sketch of the property, wherein the second instance of the sketch of the property is more accurate as compared to the first instance of the sketch of the property; and presenting the second instance of the sketch of the property via the user interface of the communication device.

In some embodiments, the method(s) described herein may be implemented using one or more communication devices. As an example, the communication device(s) may include a number of different sensors in addition to one or more cameras. A communication device may specifically include: a camera; a user interface; one or more sensors; a processor coupled with the camera, the user interface, and the one or more processors; and computer memory coupled with the processor, wherein the computer memory comprises instructions stored thereon that, when processed by the processor, enable the processor to: present, via the user interface, a video image of a property captured by the camera; enable a selection of a plurality of features of interest associated with the property via the user interface; track a motion of the communication device using the one or more sensors as the communication device travels between adjacent features of interest in the plurality of features of interest; record a location associated with each of the plurality of features of interest upon receiving the selection of each of the plurality of features of interest; determine a distance between at least two features of interest in the plurality of features of interest based on the motion of the communication device; and based on the location associated with each of the plurality of features of interest and based on the distance between the at least two features of interest, generate a first instance of a sketch of the property.

According to at least some aspects, the processor may further be configured to provide the first instance of the sketch of the property to post-processing functionality that normalizes anomalies and/or reconciles features in the first instance of the sketch of the property.

A system is also described herein that includes: a processor; and computer memory coupled with the processor, wherein the computer memory comprises instructions stored thereon that, when processed by the processor, enable the processor to: present, via a user interface of a communication device, a video image of a property captured by a camera; enable a user to select a plurality of features of interest associated with the property via the user interface; track a motion of the communication device using one or more sensors of the communication device as the communication device travels between adjacent features of interest in the plurality of features of interest; record a location associated with each of the plurality of features of interest upon receiving the selection of each of the plurality of features of interest; determine a distance between at least two features of interest in the plurality of features of interest based on the motion of the communication device; and based on the location associated with each of the plurality of features of interest and based on the distance between the at least two features of interest, generate a first instance of a sketch of the property.

According to at least some aspects, the processor may further be configured to provide the first instance of the sketch of the property to post-processing functionality that normalizes anomalies and/or reconciles features in the first instance of the sketch of the property.

The term “computer-readable medium,” as used herein, may refer to any tangible data storage medium that participates in providing instructions to a processor for execution. Such a medium may take many forms, including but not limited to, non-volatile media, volatile media, and transmission media. Non-volatile media includes, for example, NVRAM, or magnetic or optical disks. Volatile media includes dynamic memory, such as main memory. Common forms of computer-readable media include, for example, a floppy disk, a flexible disk, hard disk, magnetic tape, or any other magnetic medium, magneto-optical medium, a CD-ROM, any other optical medium, punch cards, paper tape, any other physical medium with patterns of holes, a RAM, a PROM, and EPROM, a FLASH-EPROM, a solid state medium like a memory card, any other memory chip or cartridge, or any other medium from which a computer can read instructions. When the computer-readable medium is configured as part of a database, it is to be understood that the database may be any type of database, such as relational, hierarchical, object-oriented, and/or the like. Accordingly, the disclosure is considered to include a tangible storage medium or distribution medium and prior art-recognized equivalents and successor media, in which the software implementations of the present disclosure are stored.

As used herein, “credential information” may be any data, set of data, encryption scheme, key, and/or transmission protocol used by a particular device (e.g., a “credential device”) to authenticate and/or verify its authenticity with a reader, and/or interrogator.

The phrases “at least one,” “one or more,” and “and/or” are open-ended expressions that are both conjunctive and disjunctive in operation. For example, each of the expressions “at least one of A, B and C,” “at least one of A, B, or C,” “one or more of A, B, and C,” “one or more of A, B, or C” and “A, B, and/or C” means A alone, B alone, C alone, A and B together, A and C together, B and C together, or A, B and C together. When each one of A, B, and C in the above expressions refers to an element, such as X, Y, and Z, or class of elements, such as X₁-Xₙ, Y₁-Yₘ, and Z₁-Zₒ, the phrase is intended to refer to a single element selected from X, Y, and Z, a combination of elements selected from the same class (e.g., X₁ and X₂) as well as a combination of elements selected from two or more classes (e.g., Y₁ and Zₒ).

The term “a” or “an” entity may refer to one or more of that entity. As such, the terms “a” (or “an”), “one or more” and “at least one” can be used interchangeably herein. It is also to be noted that the terms “comprising”, “including”, and “having” can be used interchangeably.

The terms “determine,” “calculate,” and “compute,” and variations thereof, as used herein, may be used interchangeably and include any type of methodology, process, mathematical operation, or technique.

The term “means” as used herein shall be given its broadest possible interpretation in accordance with 35 U.S.C., Section 112, Paragraph 6. Accordingly, a claim incorporating the term “means” shall cover all structures, materials, or acts set forth herein, and all of the equivalents thereof. Further, the structures, materials or acts and the equivalents thereof shall include all those described in the summary of the invention, brief description of the drawings, detailed description, abstract, and claims themselves.

The term “module” as used herein refers to any known or later developed hardware, software, firmware, artificial intelligence, fuzzy logic, or combination of hardware and software that is capable of performing the functionality associated with that element.

It should be understood that every maximum numerical limitation given throughout this disclosure is deemed to include each and every lower numerical limitation as an alternative, as if such lower numerical limitations were expressly written herein. Every minimum numerical limitation given throughout this disclosure is deemed to include each and every higher numerical limitation as an alternative, as if such higher numerical limitations were expressly written herein. Every numerical range given throughout this disclosure is deemed to include each and every narrower numerical range that falls within such broader numerical range, as if such narrower numerical ranges were all expressly written herein.

The preceding is a simplified summary of the disclosure to provide an understanding of some aspects of the disclosure. This summary is neither an extensive nor exhaustive overview of the disclosure and its various aspects, embodiments, and configurations. It is intended neither to identify key or critical elements of the disclosure nor to delineate the scope of the disclosure but to present selected concepts of the disclosure in a simplified form as an introduction to the more detailed description presented below. As will be appreciated, other aspects, embodiments, and configurations of the disclosure are possible utilizing, alone or in combination, one or more of the features set forth above or described in detail below.

### BRIEF DESCRIPTION OF THE DRAWINGS

The present disclosure is described in conjunction with the appended figures, which are not necessarily drawn to scale:

FIG. 1 illustrates a system according to at least some embodiments of the present disclosure;

FIG. 2 illustrates details of a mobile device according to at least some embodiments of the present disclosure;

FIG. 3 illustrates details of a server according to at least some embodiments of the present disclosure;

FIG. 4 illustrates an example of captured data and post-processed data according to at least some embodiments of the present disclosure;

FIG. 5A illustrates a first screen capture of a user interface provided by an exterior sketching application according to at least some embodiments of the present disclosure;

FIG. 5B illustrates a second screen capture of a user interface provided by an exterior sketching application according to at least some embodiments of the present disclosure;

FIG. 5C illustrates a third screen capture of a user interface provided by an exterior sketching application according to at least some embodiments of the present disclosure;

FIG. 5D illustrates a fourth screen capture of a user interface provided by an exterior sketching application according to at least some embodiments of the present disclosure;

FIG. 5E illustrates a fifth screen capture of a user interface provided by an exterior sketching application according to at least some embodiments of the present disclosure;

FIG. 6 illustrates details of a sketching method according to at least some embodiments of the present disclosure;

FIG. 7 illustrates details of a first post-processing method according to at least some embodiments of the present disclosure;

FIG. 8 illustrates details of a second post-processing method according to at least some embodiments of the present disclosure;

FIG. 9 illustrates a workflow for an interior scanning method according to at least some embodiments of the present disclosure;

FIG. 10A illustrates a first screen capture of an interior scanning user interface according to at least some embodiments of the present disclosure;

FIG. 10B illustrates various Graphical User Interface (GUI) elements used to support an interior property scanning method according to at least some embodiments of the present disclosure;

FIG. 11 illustrates scan method selection GUI elements according to at least some embodiments of the present disclosure;

FIG. 12A illustrates a first example of an interior scanning GUI element according to at least some embodiments of the present disclosure;

FIG. 12B illustrates a second example of an interior scanning GUI element according to at least some embodiments of the present disclosure;

FIG. 12C illustrates a third example of an interior scanning GUI element according to at least some embodiments of the present disclosure;

FIG. 12D illustrates a fourth example of an interior scanning GUI element according to at least some embodiments of the present disclosure; and

FIG. 12E illustrates a fifth example of an interior scanning GUI element according to at least some embodiments of the present disclosure.

### DETAILED DESCRIPTION

Before any embodiments of the disclosure are explained in detail, it is to be understood that the disclosure is not limited in its application to the details of construction and the arrangement of components set forth in the following description or illustrated in the following drawings. The disclosure is capable of other embodiments and of being practiced or of being carried out in various ways. Also, it is to be understood that the phraseology and terminology used herein is for the purpose of description and should not be regarded as limiting. The use of “including,” “comprising,” or “having” and variations thereof herein is meant to encompass the items listed thereafter and equivalents thereof as well as additional items.

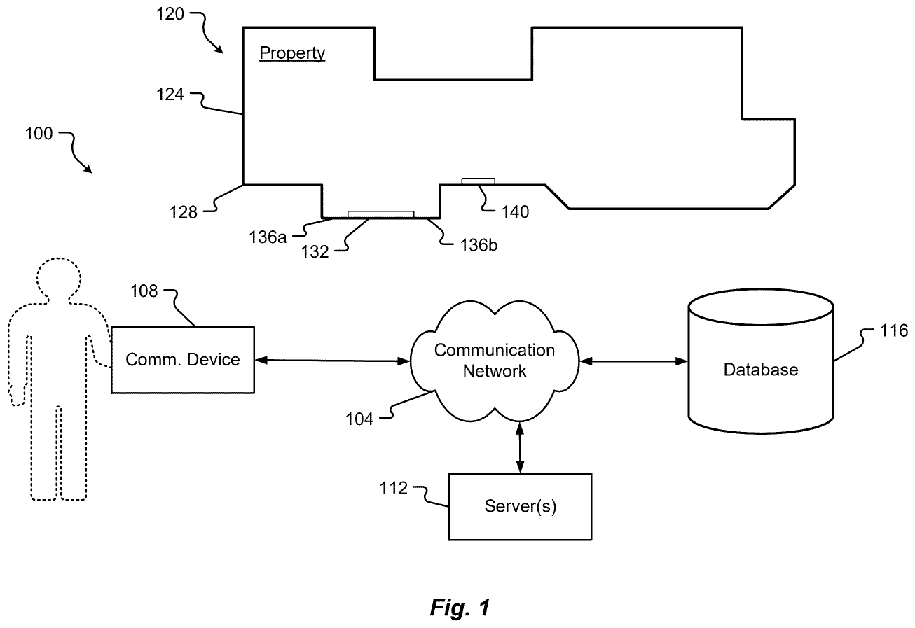

With reference to FIG. 1, an illustrative system 100 will be described in accordance with at least some embodiments of the present disclosure. The system 100 is shown to include at least a network 104, a communication device 108, one or more servers 112, and a database 116. In some embodiments, the communication device 108 may correspond to a mobile communication device, such as a smartphone, tablet, laptop, or the like. The communication device 108 may be carried by a user and may facilitate the scanning of a property 120. In some embodiments, functionality that facilitates a mapping or sketching of the property 120 is provided on the communication device 108 and/or server(s) 112. Data used to support the generation of a map or property sketch may be stored in database 116 and may be accessible to one or both of the communication device 108 and server(s) 112.

Communications in the system 100 may be facilitated by wired or wireless connections. In some embodiments, the communication network 104 may leverage wireless communication connections or protocols to facilitate device-to-device communications. Wireless communication connections or protocols that may be used within the system 100 may be provided by the communication network 104 and can include communications at least one of conventional radio protocols, proximity-based wireless communication protocols, Bluetooth™, BLE, infrared, audible, NFC, RF, Zigbee, WiFi, and other wireless communication networks and/or protocols.

The communication network 104 can facilitate communication via at least one of conventional radio networks, wireless communication networks, Zig-Bec, GSM, CDMA, WiFi, and/or using other communication networks and/or protocols as provided herein. The communication network 104 may comprise any type of known communication medium or collection of communication media and may use any type of protocols to transport messages between endpoints. The communication network 104 may include wired and/or wireless communication technologies. The Internet is an example of the communication network 104 that constitutes an Internet Protocol (IP) network consisting of many computers, computing networks, and other communication devices located all over the world, which are connected through many telephone systems and other means. Other examples of the communication network 104 include, without limitation, a standard Plain Old Telephone System (POTS), an Integrated Services Digital Network (ISDN), the Public Switched Telephone Network (PSTN), a Local Area Network (LAN), a Wide Area Network (WAN), a Session Initiation Protocol (SIP) network, a Voice over Internet Protocol (VOIP) network, a cellular network, RS-232, RS-485, similar networks used in access control systems between readers and control panels, and any other type of packet-switched or circuit-switched network known in the art. In addition, it can be appreciated that the communication network 104 need not be limited to any one network type, and instead may be comprised of a number of different networks and/or network types. Moreover, the communication network 104 may comprise a number of different communication media such as coaxial cable, copper cable/wire, fiber-optic cable, antennas for transmitting/receiving wireless messages, and combinations thereof.

The server(s) 112 may include one or more functions that coordinate with functions provided by the communication device 108. Said another way, the communication device 108 may interact with the server(s) 112 as part of providing functionality described herein (e.g., scanning and sketching functionality, post-processing functionality, user interface functionality, etc.).

As noted above, the communication device 108 may include any type of known computational device that facilitates communications for a user thereof. Non-limiting examples of communication devices 108 include a mobile phone, a cellular phone, a smartphone, a Personal Computer (PC), a laptop, a tablet, a Personal Digital Assistant (PDA), or the like.

The database 116 may include one or more data storage locations that are accessible to the communication device 108 and/or server(s) 112. The database 116 may be used to store data that is used to generate sketches, facilitate post-processing of sketches, render sketches, and the like. The database 116 may be securely maintained such that only limited access is granted to particular data, meaning that unauthenticated users are not allowed to access secured data.

The communication device 108 may be carried by the user around the property 120 to scan and capture information about the property 120. Specifically, and without limitation, the communication device 108 can be used to capture information describing one or more features of interest 124, 128, 132, 136a, 136b, and/or 140. Examples of features of interest include walls 124, corners 128, windows 132, window-containing walls 136a, 136b, and doors 140. As the user walks around the property 120, various cameras, sensors, and other devices of the communication device 108 may track a location of the user and record location information associated with each recorded feature of interest. After all features of interest have been recorded with the communication device 108 and the locations associated therewith have also been recorded, the communication device 108 may utilize functionality provided thereon to generate a first instance of a map or sketch of the property 120 and the physical relationship between the recorded features of interest. Alternatively or additionally, the server 112 may be used to generate the first instance of a map or sketch of the property 120.

The communication device 108 and/or server(s) 112 may also be configured to provide post-processing functionality that improves the first instance of the map or sketch. For instance, the post-processing functionality may be configured to generate a second instance of the map or sketch that improves an accuracy of the first instance of the map or sketch and/or removes anomalies therefrom.

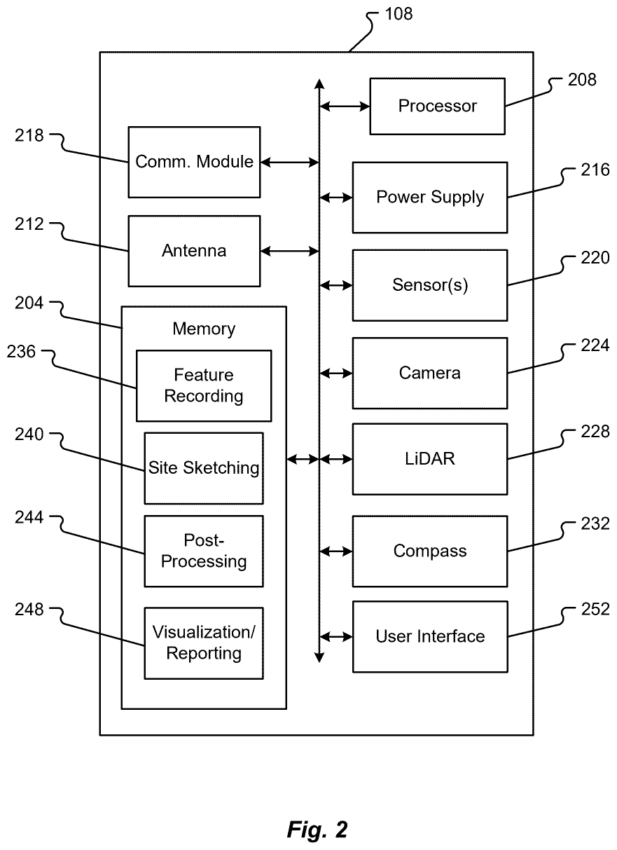

Referring now to FIG. 2, a block diagram depicting a communication device 108 is shown in accordance with embodiments of the present disclosure. The communication device 108 may include one or more components, such as, a memory 204, a processor 208, an antenna 212 (or multiple antennas 212), a communications module 218, one or more sensors 220, a camera 224, a LIDAR module 228, a compass 232, and a user interface 252. While not depicted, the communication device 108 may further include a GPS module that facilitates a determination of global location for the communication device 108 using satellite triangulation.

The processor 208 may correspond to one or many microprocessors that are contained within the housing of the communication device 108 with the memory 204. In some embodiments, the processor 208 incorporates the functions of the communication device's 108 Central Processing Unit (CPU), Graphics Processing Unit (GPU), or the like, on a single Integrated Circuit (IC) or a few IC chips. Alternatively or additionally, the processor 208 may include an Application Specific Integrated Circuit (ASIC), Field Programmable Gate Array (FPGA), or the like. The processor 208 may be a multipurpose, programmable device that accepts digital data as input, processes the digital data according to instructions stored in its internal memory, and provides results as output. The processor 208 may alternatively or additionally implement sequential digital logic as it has internal memory. As with most known microprocessors, the processor 208 may operate on numbers and symbols represented in the binary numeral system.

The one or more antennas 212 may be configured to enable wireless communications between the communication device 108 and communication network 104, and/or some other device. As can be appreciated, the antenna(s) 212 may be arranged to operate using one or more wireless communication protocols and operating frequencies including, but not limited to, Bluetooth®, NFC, Zig-Bec, GSM, CDMA, WiFi, RF, and the like. By way of example, the antenna(s) 212 may be RF antenna(s), and as such, may transmit RF signals through free-space to be received by another device having an RF transceiver. One or more of the antennas 212 may be driven or operated by a dedicated antenna driver.

The memory 204 of the communication device 108 may be used in connection with the execution of application programming or instructions by the processor 208, and for the temporary or long-term storage of program instructions and/or data. The memory 204 may contain executable instructions or functions that are used by the processor 208 to run other components of the communication device 108. In one embodiment, the memory 204 may be configured to store instructions in the form of a feature recording 236, property sketching 240, post-processing 244, and visualization/reporting functions 240, among other instructions. In some embodiments, the memory 204 may comprise volatile or non-volatile memory and a controller for the same. Non-limiting examples of memory 204 that may be utilized in the communication device 108 include RAM, ROM, buffer memory, flash memory, solid-state memory, or variants thereof.

The feature recording 236, when executed by the processor 208, may be configured to receive data from a number of other components of the communication device 108 and utilize such data in connection with recording features of interest associated with a property 120. For instance, and without limitation, the feature recording 236 can be configured to track a location of the communication device 108 using one or more sensors 220 provided on the communication device 108. Illustratively, the feature recording 236 may utilize location data or motion data obtained from a sensor 220, such as an inertial motion sensor (IMU), a motion sensor, a LiDAR sensor, a light sensor, and/or any other type of sensor. Alternatively or additionally, the feature recording 236 may utilize location data obtained from a GPS and/or a compass 232. The feature recording may also utilize data from the LiDAR 228 as features of interest associated with a property 120 are captured by a user of the communication device 108.

For instance, as a user moves around (or within) a property 120, the feature recording 236 may be configured to track when a user selects a feature of interest via the user interface 252. The feature recording 236 may also be configured to determine a location associated with the feature of interest (e.g., using data from the IMU, compass, GPS, LiDAR, etc.). As features of interest are recorded by the user of the communication device, the feature recording 236 may be configured to store an order in which features of interest are captured by the user as well as data associated with the feature of interest (e.g., location, wall length, angles, feature type, etc.).

The feature recording 236 may be configured to provide the information recorded in connection with a feature of interest or a collection of features of interest to the site sketching 240. The site sketching 240, when executed by the processor 208, may be configured to generate a partial or complete map or sketch of the property 120 using data obtained from the feature recording 236. In some embodiments, the site sketching 240 may be configured to generate a first instance of a property sketch, which is generated using the raw data obtained from the feature recording 236.

The site sketching 240 may be configured to communicate information describing a first instance of the property sketch to post-processing functions 244. The post-processing functions 244, as will be described in further detail herein, may be configured to generate one or more additional instances (e.g., a second or third instance) of the property sketch using information obtained from the site sketching 240. In some embodiments, the post-processing functions 244 may be configured to normalize data, angles, locations, and dimensions of the property 120 in the first instance of the property sketch. In some embodiments, the post-processing functions 244 may help generate a more accurate and comprehensive representation of the property 120. In addition to providing normalization, the post-processing functions 244 may also remove anomalies and/or reconcile discrepancies between various dimensions of different features of interest. For example, post-processing functions 244 may normalize anomalies and/or reconciles the features in an instance of a sketch of a property using an averaging function and/or a centering function.

The visualization/reporting 248, when executed by the processor 208, may be configured to receive inputs from the site sketching 240 and/or post-processing functions 244 and generate one or more representation of the property 120. For instance, the visualization/reporting 248 may be configured to generate one or more renderings of a map or sketch generated by the site sketching 240 and/or post-processing functions 244, then present the map or sketch via the user interface 252.

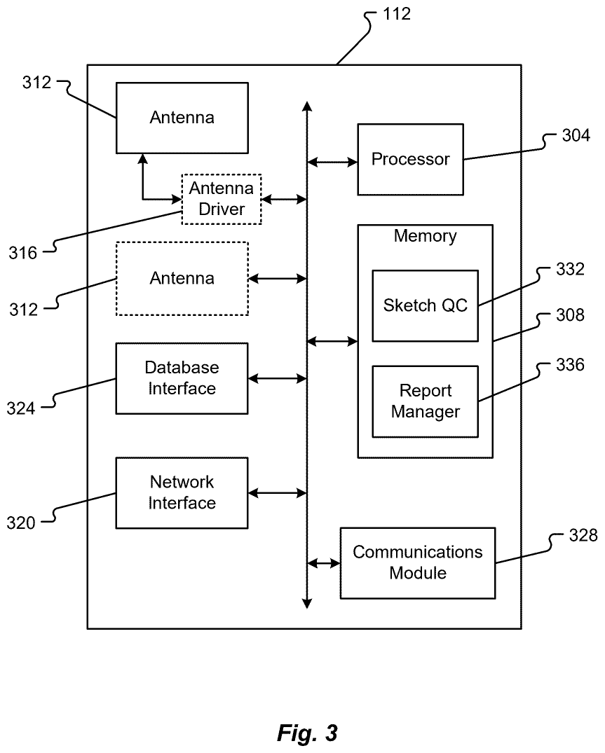

Referring now to FIG. 3, additional details of a server 112 will be described in accordance with at least some embodiments of the present disclosure. It should be appreciated that some or all components depicted and described in connection with the communication device 108 may be incorporated into a server 112. Likewise, some or all components depicted and described in connection with the server 112 may be incorporated into a communication device 108 without departing from the scope of the present disclosure.

The server 112 is illustrated to include a processor 304, memory 308, one or more antennas 312, an antenna driver 316, a network interface 320, a database interface 324, and a communications module 328. In some embodiments, the server 112 may include a power module. The power module may be configured to provide power to the parts of the server 112 to support operation thereof. The power module may store power in a capacitor of the power module, may include one or more DC power sources (e.g., batteries), may include one or more AC power sources (e.g., a power transformer or converter that conditions power received from an external AC power source. As a non-limiting example, the power module may include a battery or other power source to supply power to parts of the server 112. The power module may include a built-in power supply (e.g., battery) and/or a power converter that facilitates the conversion of externally-supplied AC power into DC power that is used to power the various components of the server 112. In some embodiments, the power module may also include some implementation of surge protection circuitry to protect the components of the server 112 from power surges.

The communications module 328 may be configured to communicate with one or more different systems or devices either remotely or locally. Thus, the communications module 328 can be configured to format data packets for transmission by an antenna 212 and/or network interface 320. The communications module 328 may be responsible for enabling the server 112 to receive data, extract data from data packets received at an appropriate interface or antenna, receive reports or information for transmission to a communication device 120, format data packets to include the reports or information for transmission to a communication device 120, and generally enable the communication device 108 to exchange communications with other devices in the system 100.

In some embodiments, components of the communications module 228 may include components that operate with the physical interface(s) of the server 112 (e.g., antenna(s) 212, network interface 320, database interface 324, communications module 328, etc.). In some embodiments, the communications module 328 and one or more physical interfaces may be provided in an Ethernet port, a WiFi card, a Network Interface Card (NIC), or the like.

The processor 304 may be similar or identical to processor 208. In some embodiments, the processor 304 may be configured to execute instructions stored in memory 308. The processor 304 may also be configured to operate other components of the server 112 based on a state of the server 112.

The memory 308 may be similar or identical to memory 204 and may be configured to store instructions for execution by the processor 304. The memory 308 may also be configured to store instructions for execution by the processor 304. Illustrative instructions that may be stored in memory 308 include, without limitation, sketch quality control instructions 332 and report management instructions 336.

The sketch quality control instructions 332, when executed by the processor 304, may be configured to analyze a first instance of a property sketch or map, a second instance of a property sketch or map, or later instance of a property sketch or map. The sketch quality control instructions 332 may be configured to ensure that a sketch or map complies with predetermined accuracy thresholds or tolerances. Alternatively or additionally, the sketch quality control instructions 332 may be configured to receive one instance of a sketch or map which fails to comply with predetermined accuracy thresholds or tolerances and, in response thereto, may provide the sketch or map to post-processing functionality 224 for further processing and refinement.

The report management instructions 336, when executed by the processor 304, may be configured to determine which instance of a sketch or map should be stored in the database 116. Alternatively or additionally, the report management instructions 336 may be configured to store a plurality of instances of a sketch or map in the database 116 for later retrieval or comparison to previous instances of a sketch or map. The report management instructions 336 may also be configured to determine when to present an instance of a sketch or map to a user via a communication device 108 and retrieve the appropriate instance of the sketch or map from the database 116 for transmission to the communication device 108.

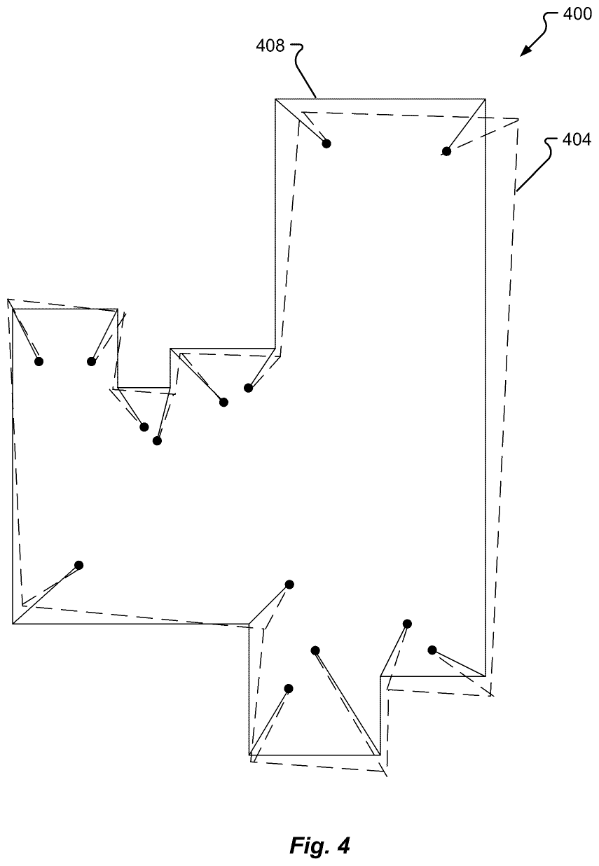

As shown in FIG. 4, a sketch or map 400 of a property 120 may have a number of instances associated therewith. In some embodiments, a first instance 404 of the sketch or map 400 of the property 120 is shown relative to a second instance 408 of the sketch or map 400 of the property 120. The second instance 408 may correspond to an instance of the sketch or map 400 after post-processing 244 has been applied to the first instance 404. The first instance 404 may correspond to a sketch or map generated based on the raw data captured by a communication device 108 while a user walks around a property 120. The second instance 408 may correspond to a sketch or map that has anomalies removed from the first instance 404 and/or corresponds to a normalized version of the first instance 404. As will be described in further detail herein, the second instance 408 may have walls 124 positioned orthogonally relative to adjacent walls. The second instance 408 may also have corners 128 existing at or near 90 degrees, when appropriate. The second instance 408 may also have window-containing walls 136a, 136b coplanar with one another and coplanar with a window 132 contained therein.

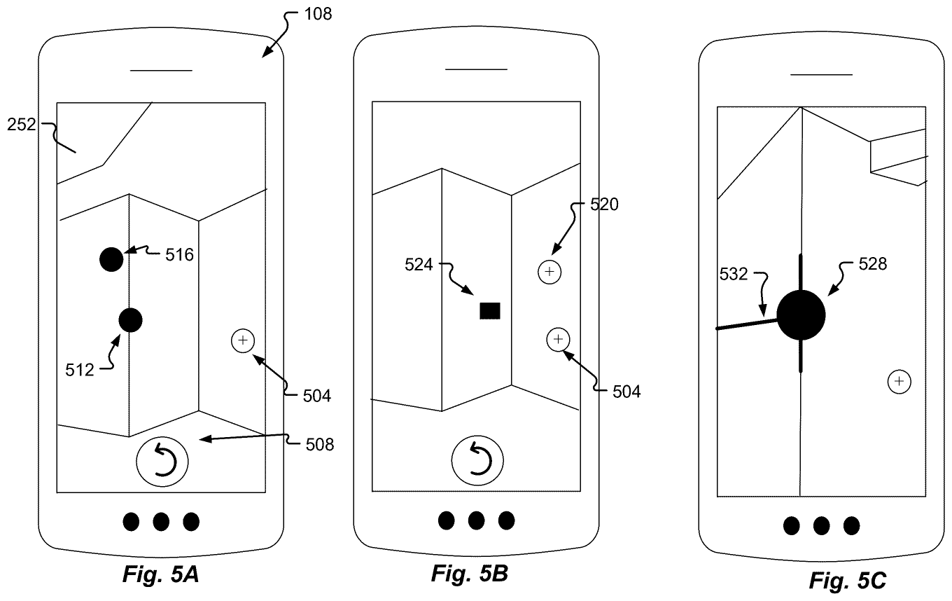

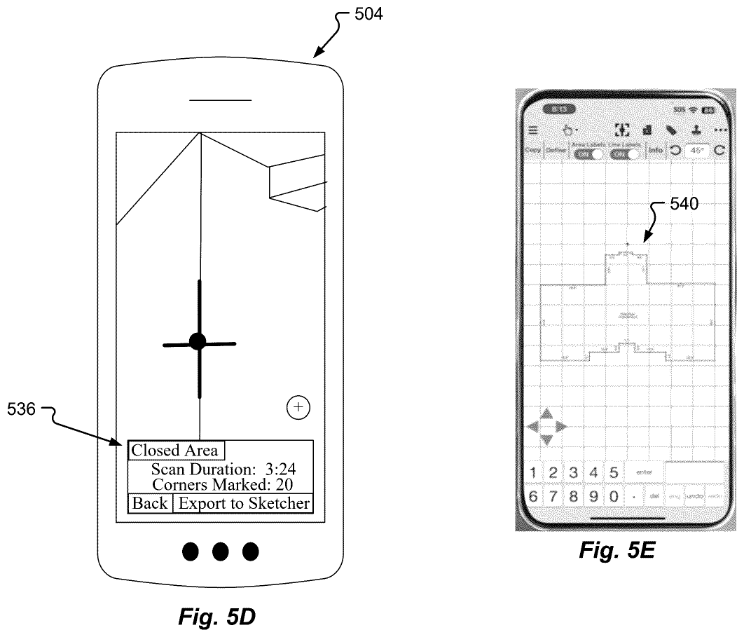

Referring now to FIG. 5A-5E, various screen shots of a user interface 252 will be described in accordance with at least some embodiments of the present disclosure for creating a sketch of the exterior outline and shape of the property via scanning of the exterior corners of the property. Illustratively, FIG. 5A shows a user interface 252 presenting a capture icon 504, an undo icon 508, a feature locator 512, and a confirmation bubble 516. The user may tap or press the capture icon 504 when the feature locator 512 is positioned over a feature of interest (such as for example an exterior corner of the property) and the user desires to mark that particular feature as a next feature of interest. In the example of FIG. 5A, the feature locator 512 is presented over an exterior corner 128 of the property 120. The user may determine that the exterior corner 128 is the next feature of interest to record during their capture of the property 120 and its various features. When the user determines that the feature locator 512 is appropriately positioned over the image of the feature of interest within the camera view, the user may tap or press the capture icon 504. If a feature was inadvertently captured, then the user may tap or press the undo icon 508 to un-record the previously-recorded feature. When the capture icon 504 is engaged (e.g., tapped or pressed), then the communication device 108 may record location information associated with the feature of interest as well as distance information from a previously-recorded feature of interest (e.g., wall length).

After a particular feature of interest is recorded, the user may walk with the communication device in a face-down arrangement (e.g., having the camera 224 facing the ground) such that other sensors 220 (e.g., IMUs, GPS, etc.), a compass 232, or the like can determine an amount of distance traveled by the communication device 108 between features of interest. The LiDAR 228 may also be used to measure distances between features of interest and/or to facilitate the automated placement of the feature locator 512 over a potential feature of interest, thereby facilitating an easier capture of features of interest by the user.

FIG. 5B illustrates that different types of capture icons can be presented by the user interface 252. In particular, an auto-capture icon 520 can be used in addition to or in lieu of a manual capture icon 504. In embodiments where the auto-capture icon 520 is used (e.g., where less user input is required to identify features of interest), the user interface 252 may also present a feature highlighter 524 that shows a location of a feature of interest that has been automatically captured by the communication device 108.

FIG. 5C illustrates a corner locator 528 along with a wall dimension 532. The corner locator 528 may be similar to the feature locator 512, but may correspond to a larger presentation of a graphical user interface (GUI) element showing where the corner 128 exists relative to the image of the property 120. The wall dimension 532 may correspond to a presentation of a line or ray from a last feature of interest to the next corner locator 528 (or feature locator 512).

FIG. 5D illustrates a summary window 536 in which statistics and/or dimensional information associated with a property 120 are summarized after the property has been walked by the user and after features of interest have been captured with the communication device 108. In some embodiments, the summary window 536 may present information describing how long the property scan took (e.g., scan duration) as well as the number and/or type of features captured (e.g., number of corners marked). The summary window 536 may also indicate whether the features of interest created a closed or unclosed area (e.g., correspond to a complete representation of a property 120 or an incomplete representation of a property). In some embodiments, an unclosed area may indicate less than all features of interest have been captured.

FIG. 5E illustrates a presentation of a sketch or map 540 of the exterior of the property 120. The sketch or map 540 may correspond to a first, second, third, . . . , Nth instance of a sketch or map 540 of the exterior of the property 120. The sketch or map 540 may correspond to the working representation of the outline or shape of property 120 to be used for other purposes (e.g., project estimation, valuation, etc.). The sketch or map 540 may present exterior and/or interior dimensional information associated with the property (e.g., interior square footage, area, exterior wall lengths and dimensions, etc.) and/or descriptive exterior and/or interior information associated with the property (e.g., number of features of interest, types of features of interest, amount of adjustment needed between instances of a sketch or map 540 to comply with predefined thresholds).

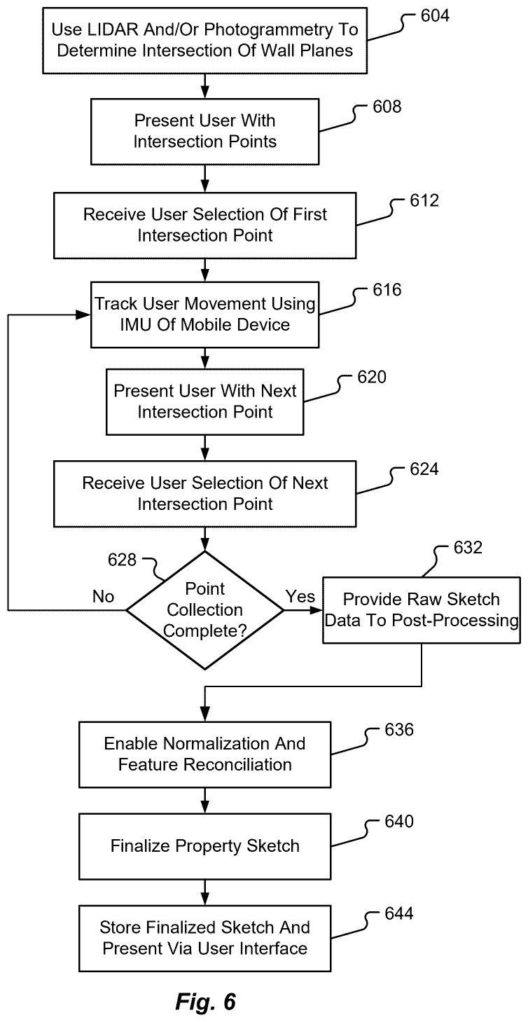

With reference to FIGS. 6-8, various methods of property sketching will be described in accordance with at least some embodiments of the present disclosure. The methods will be described with reference to particular components of a system 100, but it should be appreciated that any one component or a combination of components of the system 100 can be configured to execute the methods described herein. Moreover, it should be appreciated that the various methods may be performed in any order and steps from one method may be performed in another method without departing from the scope of the present disclosure. It should also be appreciated that the steps depicted and described in connection with FIGS. 6-8 may be performed in connection with an interior scanning method and/or exterior scanning method to create a sketch of a property. In other words, the methods of FIGS. 6-8 should not be construed as being limited to a particular type of scanning method, but rather can be applied to any suitable type of scanning method (e.g., interior and/or exterior scanning).

Referring now to FIG. 6, a first method of property sketching will be described in accordance with at least some embodiments of the present disclosure. The method begins with a user carrying a communication device 108 and using LiDAR 228 of the communication device 108 and/or photogrammetry to determine an intersection of wall planes (step 604). For instance, the LiDAR 228 and/or photogrammetry may be used to identify a location of a feature of interest and then present an animation of a feature locator 512 over top of a video image of the property 120. The feature locator 512 may be presented in an augmented reality fashion over the image of the property 120 (step 608).

The method continues when a user input is received at the user interface 252 of the communication device 108 indicating a selection of a first intersection point (step 612). In some embodiments, the selection of the first intersection point may correspond to a selection of a first feature of interest, which may include a corner 128 of the property 120 (e.g., an intersection of two distinct walls 124).

After the first intersection point or first feature of interest is selected, the method continues by tracking a movement of the user as the user carries the communication device 108 around the property 120 (step 616). In particular, an IMU, GPS, and/or compass 232 of the communication device 108 may be used to track a physical location of the communication device 108 from the position where the first feature of interest was selected to a second position relative to the property 120. The movement of the communication device 108 may be tracked as the user holds the communication device 108 in a face-down orientation, thereby facilitating a more accurate capture of location information from the communication device 108.

The method then continues when the user holds the communication device 108 up toward the property 120 and faces the camera 224 toward the property again. As an image of the property is presented to the user via the user interface 252, the user may also be presented with a next intersection point or feature of interest (step 620). As an example, the user may be presented with another feature locator 512 overlaid on a video image of the property 120. The feature locator 512 may be positioned within the video image of the property 120 using LiDAR and/or photogrammetry such that the feature locator 512 identifies a location in the image of a feature of interest, such as another corner 128 of the property 120. In some embodiments, the next feature of interest or next corner 128 may correspond to a corner 128 that shares a wall 124 with the first corner 128 selected in step 612. In other words, the next feature of interest may be considered adjacent to the first feature of interest.

The method proceeds when the user selects the next feature of interest using the capture icon 504 and/or 520 (step 624). The process of step 624 may be similar to step 612 in that the user selection is received at the user interface 252 and when the user selection of the next feature of interest is received, the location information associated with the next feature of interest is recorded along with other information describing the next feature of interest. Other information describing the next feature of interest may include a description of the type of feature. The location information associated with the next feature may include absolute location information relative to a common coordinate system and/or a distance from the first feature of interest.

The method proceeds by determining whether the point collection process is complete (step 628). If step 628 is answered negatively, then the method returns to step 616 and feature capture continues in combination with tracking a movement of the communication device 108. If, however, step 628 is answered positively, then the method continues with the feature recording 236 providing the raw sketch data to site sketching 240 such that a first instance of a sketch or map of the property 120 is generated.

The site sketching 240 may then provide the first instance of the sketch or map of the property 120 to post-processing 244 (step 632). The post-processing 244 may then process the data used to generate the first instance of the sketch or map of the property 120 to normalize certain aspects of the data and/or to remove anomalies from the data, thereby facilitating the creation of a more accurate sketch or map of the property 120 (step 640). The finalized sketch or map of the property 120 may then be presented to the user via the user interface 252. The visualization and reporting 248 may also cause the finalized sketch or map of the property 120 to be stored in a database 116. In addition to storing the sketch or map of the property 120, the data used to generate the finalized sketch or map of the property 120 along with dimensional details of the property 120 may be stored in the database 116. For example, locations and other related information of each recorded feature of interest may be stored along with an order in which each feature of interest was stored.

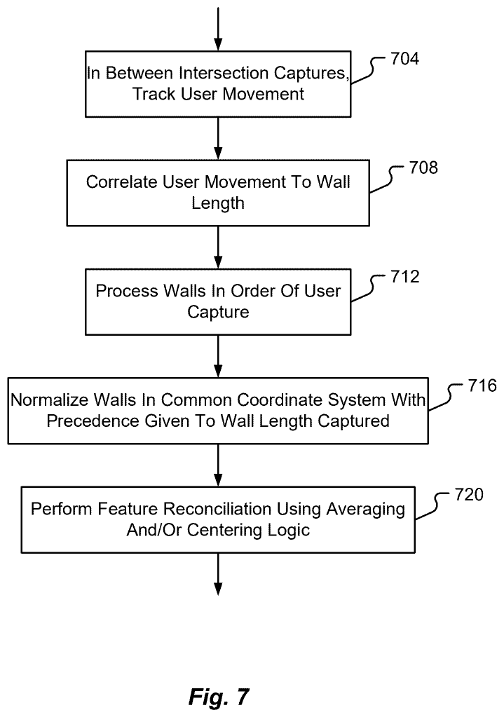

With reference now to FIG. 7, a second method of property sketching will be described in accordance with at least some embodiments of the present disclosure. The method may be performed in combination with the method of FIG. 6. Steps of FIG. 7 may be performed before, after, or in parallel with steps of FIG. 6.

The method begins by tracking user movement in between intersection captures (step 704). As discussed above, user movement may be tracked with an IMU, compass 232, and/or GPS of the communication device 108 as the communication device 108 is carried around the property 120 between features of interest. Movement of the communication device 108 may be correlated to dimensional information for the property 120. For example, movement of the communication device 108 between captures of corners 128 may be correlated to wall length (step 708).

The method may continue by performing post-processing of some or all data captured with the communication device 108 as the user walked around the property 120. As an example, the method may continue by processing each of the walls according to the order in which features were captured (step 712). The proposed post-processing may normalize anomalies that arise from the slight inaccuracies of the IMU and/or compass 232 on the communication device 108. Walls may be normalized to segmented degree increments within a set tolerance. For instance, if a first wall 124 exists at 96 degrees relative to world 0 degrees, the first wall is normalized to 90 degrees and the connecting adjacent walls 124 are adjusted/healed to maintain property connections. Walls may be processed in an order in which a user captured them. Precedence is given to preserving wall length captured, due to the length having far a greater accuracy to the wall angle (step 716). As each wall is processed to complete world angle normalization, subsequent walls are adjusted by the same angle, rotated around the starting point of the wall being processed.

After wall adjustments are made, the method may further include performing feature reconciliation using averaging and/or centering logic (step 720).

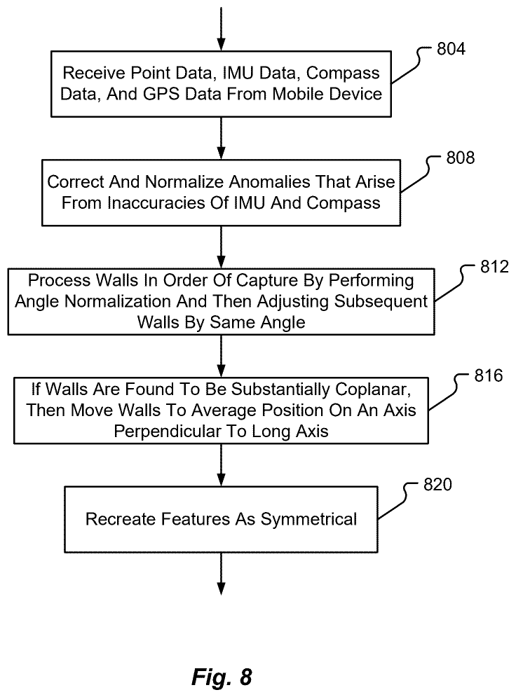

Referring now to FIG. 8, another method of property sketching will be described in accordance with at least some embodiments of the present disclosure. The method may be performed in combination with the method of FIG. 6 and/or FIG. 7. Steps of FIG. 8 may be performed before, after, or in parallel with steps of FIG. 6 and/or FIG. 7.

The method begins by receiving point data, IMU data, compass data, and/or GPS data from a communication device 108, such as a mobile device (step 804). The data may also indicate an order in which each point data (e.g., a feature of interest) was captured relative to other features of interest.

The method continues by correcting and normalizing anomalies that arise from inaccuracies of the IMU and/or compass 232 (step 808). The method may also include processing walls in the order of capture by performing angle normalization and then adjusting subsequent walls by the same angle, as discussed in connection with FIG. 7 (step 812).

The method may then include an additional post-processing function where feature reconciliation is completed. Illustratively and without limitation, after wall angle normalization, walls 124 can be analyzed for any walls 124 that exist on the same axis that are nearly coplanar within a set threshold. If walls 124 are found to be nearly coplanar within the set threshold, such walls 124 are each moved to their average position on the axis perpendicular to their long/running axis (step 816). After coplanar threshold processing, the post-processing 244 looks for known features that need to be made symmetrical, such as bay windows and point bay windows. The post-processing attempts to recreate the feature as symmetrical by averaging and centering with the data provided (step 820).

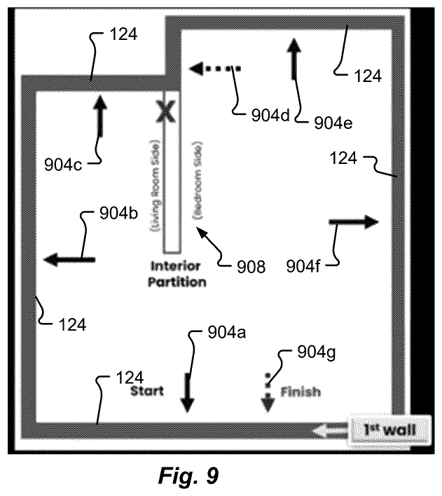

As can be seen with reference to FIG. 9, a sketch of the exterior outline and shape of the property may be generated using an interior scanning workflow in substitution of or in addition to using an exterior scanning workflow. In one example of an interior scanning workflow, features of interest, such as an interior wall 124, may be scanned as a user walks around the interior of the property. In some embodiments, the user may start at a first scanning location 904a and record a first wall 124. The user may then travel to an adjacent wall 124 and scan the adjacent wall from a second scanning location 904b. The user may continue walking around the property and may scan successive features of interest (e.g., additional walls 124) from successive scanning locations 904c, 904d, 904c, 904f. The interior scanning workflow may end with the user scanning the first scanned wall 124 from a final scanning location 904g.

FIG. 9 illustrates that interior perimeter walls may be scanned according to an order (e.g., one adjacent wall 124 at a time). The user interface 252 may present GUI elements to the user that facilitate the workflow of FIG. 9. In this particular embodiment, it may be desirable not to scan partition walls 908, since such walls do not contribute to the total area of the property. Said another way, the interior partition walls 908 only divide the interior area of the property and their length has no impact on the square footage of the property.

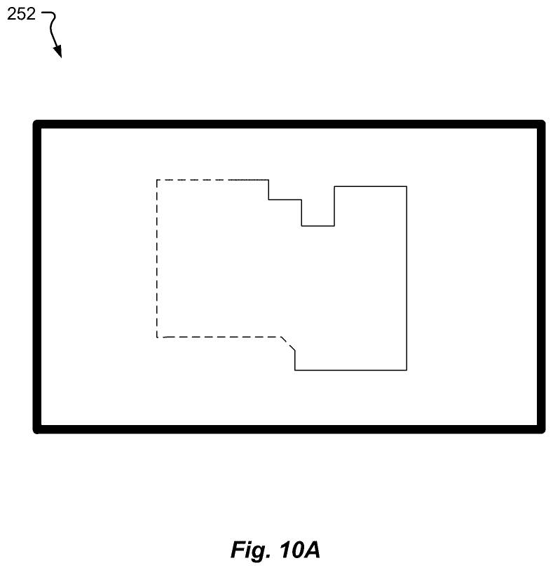

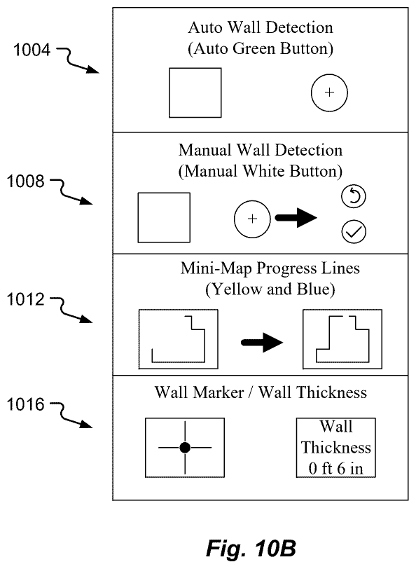

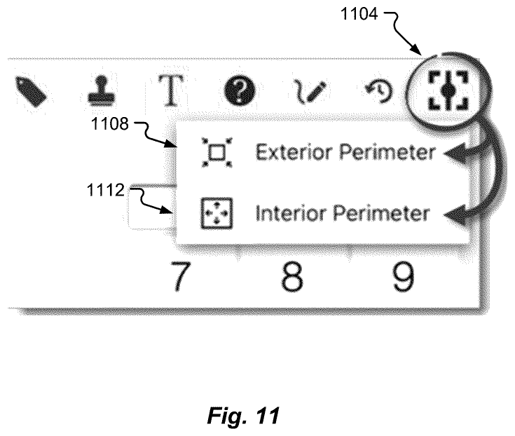

With reference now to FIGS. 10A, 10B, 11, and 12A-12E, additional examples of user interfaces 252 and GUI elements will be described in connection with an interior scanning method, which may be utilized to generate a sketch of the exterior of the property much like the various exterior scanning methods depicted and described herein.

Referring initially to FIGS. 10A and 10B, examples of GUI elements that may be presented on the user interface 252 of a communication device 108 to support an interior scanning method are shown. Specifically, GUI elements that may be presented include automated capture elements 1004, manual capture elements 1008, display elements 1012, and dimensioning elements 1016. The various GUI elements used for the interior scanning method may be similar in function and capability to the various GUI elements depicted and described in FIGS. 5A-5E.

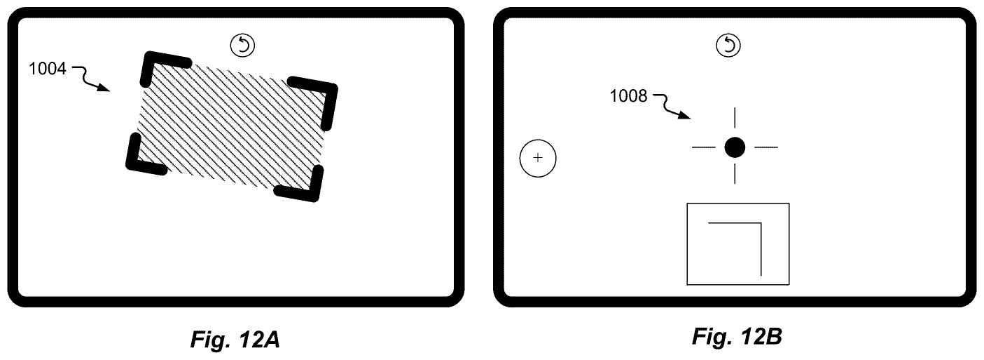

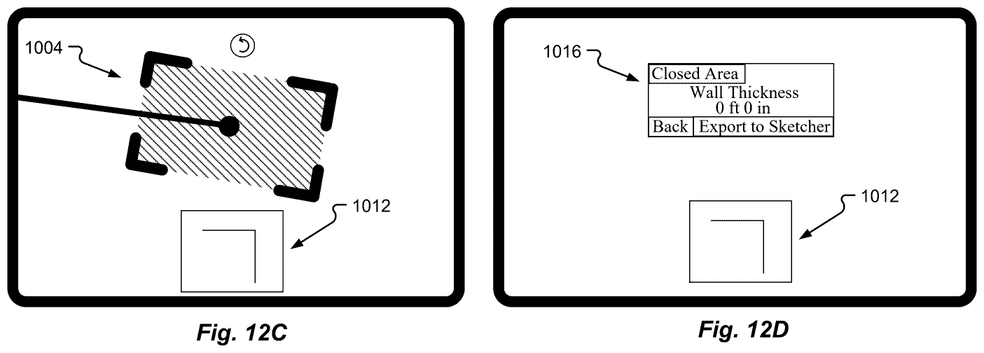

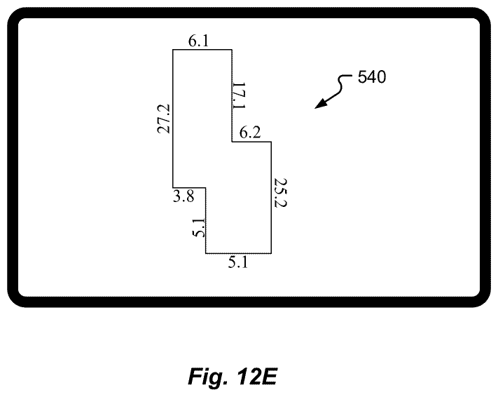

In some embodiments, it may be possible to switch the user interface 252 between an interior scanning method and an exterior scanning method. The switching of the user interface 252 may be facilitated with a scan method selection feature 1104, which may present an exterior scanning option 1108 and an interior scanning option 1112. Selection of the exterior scanning option 1108 may cause GUI elements as shown in FIGS. 5A-5E for the exterior scanning and sketching method to be presented via the user interface 252 whereas selection of the interior scanning option 1112 may cause GUI elements as shown in FIGS. 12A-12E to be presented via the user interface 252 for the interior scanning and sketching method. Embodiments contemplate the ability to use the exterior corner marking mode for identifying and recording interior corners. Conversely, it may be possible to use the interior perimeter wall marking mode for exterior walls as well.

Referring now to FIGS. 12A-12E, additional details of the GUI elements used for an interior scanning and sketching method will be described. In some embodiments, the automated capture elements 1004 may be presented over an image of a wall 124. The location of the wall 124 may be determined similar to the location of a corner 128, with use of LiDAR and/or photogrammetry. In some embodiments, the automated capture elements may include a presentation of a feature highlighter (e.g., the green box), a capture icon (e.g., the red button), and an undo icon. The user interface 252 may also present a dialog box that provides instructions for capturing a feature of interest, such as the wall 124 or an interior corner 128. The instructions provided by the dialog box may also provide instructions for carrying the communication device 108 between features of interest.

As shown in FIG. 12B, the manual capture elements 1008 may include a feature highlighter (e.g., the blue box and green dot), a capture icon (e.g., the white “+” button), and the undo icon. Capture of a feature of interest via the manual capture elements 1008 may be achieved similarly to the automated capture elements 1004, except that automated identification of a possible feature of interest with LiDAR and/or photogrammetry is not utilized.

FIG. 12C illustrates the user interface 252 presenting the automated capture elements 1004 with the display elements 1012. The display elements 1012 may present the location, orientation, and estimated length (e.g., dimension) of the previously captured features of interest (e.g., walls 124). The display elements 1012 may further show or suggest which features remain to be captured (e.g., identify gaps between captured elements).

FIG. 12D illustrates the user interface 252 presenting the display elements 1012 alongside the dimensioning elements 1016. The dimensioning elements 1016 may be used to select wall thickness or other dimension tolerances. The dimension(s) selected with the dimensioning elements 1016 may be used to extrapolate dimensions of the interior walls 124 to dimensions of the exterior walls, which are then equated to dimensions of the property/structure.

FIG. 12E presents the sketch or map 540 of the exterior outline of the property after the scanning process has been completed. While the sketch or map 540 of FIG. 12E corresponds to the exterior outline of the property that was captured with an interior scanning process, it should be appreciated that an exterior scanning process could have been used to create the same sketch or map 540 shown in FIG. 12E of the exterior outline of the property.

Embodiments of the present disclosure include a method for sketching a property, the method comprising: presenting, via a user interface of a communication device, a video image of a property; enabling a selection of a plurality of features of interest associated with the property via the user interface; tracking a motion of the communication device as the communication device travels between adjacent features of interest in the plurality of features of interest; recording a location associated with each of the plurality of features of interest upon receiving the selection of each of the plurality of features of interest; determining a distance between at least two features of interest in the plurality of features of interest based on the motion of the communication device; and based on the location associated with each of the plurality of features of interest and based on the distance between the at least two features of interest, generating a first instance of a sketch of the property.

Aspects of the method include providing the first instance of the sketch of the property to post-processing functionality that normalizes anomalies and/or reconciles features in the first instance of the sketch of the property; receiving, from the post-processing functionality, a second instance of the sketch of the property, wherein the second instance of the sketch of the property is more accurate as compared to the first instance of the sketch of the property; and presenting the second instance of the sketch of the property via the user interface of the communication device.

Aspects of the method include wherein at least one of the plurality of the features of interest comprises a corner of the property.

Aspects of the method include presenting, over the video image of the property, a feature indicator that is overlaid on the corner of the property.

Aspects of the method include wherein a position of the feature indicator is determined by at least one of a Light Detection and Ranging (LiDAR) sensor and photogrammetry.

Aspects of the method include wherein the feature indicator is overlaid on the corner of the property substantially simultaneous with receiving the selection of the corner.

Aspects of the method include referencing at least one of a compass and a motion sensor of the communication device to determine the distance between the at least two features of interest in the plurality of features of interest.

Aspects of the method include wherein the motion sensor comprises an inertial motion sensor.

Aspects of the method include referencing a Global Positioning System (GPS) of the communication device to determine the distance between the at least two features of interest in the plurality of features of interest.

Aspects of the method include providing the first instance of the sketch of the property to post-processing functionality that normalizes anomalies and/or reconciles the features in the first instance of the sketch of the property according to an order in which each of the plurality of features of interest are recorded.

Aspects of the method include wherein the plurality of features of interest comprise at least one of a corner and a perimeter wall.

Aspects of the method include providing the first instance of the sketch of the property to post-processing functionality that normalizes anomalies and/or reconciles the features in the first instance of the sketch of the property using at least one of an averaging function and a centering function.

Embodiments of the present disclosure include a communication device, including; a camera; a user interface; one or more sensors; a processor coupled with the camera, the user interface, and the one or more processors; and computer memory coupled with the processor, wherein the computer memory includes instructions stored thereon that, when processed by the processor, enable the processor to: present, via the user interface, a video image of a property captured by the camera; enable a selection of a plurality of features of interest associated with the property via the user interface; track a motion of the communication device using the one or more sensors as the communication device travels between adjacent features of interest in the plurality of features of interest; record a location associated with each of the plurality of features of interest upon receiving the selection of each of the plurality of features of interest; determine a distance between at least two features of interest in the plurality of features of interest based on the motion of the communication device; and based on the location associated with each of the plurality of features of interest and based on the distance between the at least two features of interest, generate a first instance of a sketch of the property.

Aspects of the communication device include wherein the processor is further enabled to: provide the first instance of the sketch of the property to post-processing functionality that normalizes anomalies and/or reconciles features in the first instance of the sketch of the property.

Aspects of the communication device include wherein the processor is further enabled to: receive, from the post-processing functionality, a second instance of the sketch of the property, wherein the second instance of the sketch of the property is more accurate as compared to the first instance of the sketch of the property; and present the second instance of the sketch of the property via the user interface.

Aspects of the communication device include wherein the at least one of the plurality of features of interest comprises a corner of the property and wherein the processor is further enabled to: presenting, over the video image of the property, a feature indicator that is overlaid on the corner of the property.

Aspects of the communication device include wherein the one or more sensors comprise a Light Detection and Ranging (LiDAR) sensor and/or a light sensor.

Aspects of the communication device include wherein the feature indicator is overlaid on the corner of the property substantially simultaneous with receiving the selection of the corner.

Aspects of the communication device include wherein the one or more sensors comprises at least one of a compass and a motion sensor.

Embodiments of the present disclosure include a method for sketching a property, the method including: presenting, via a user interface of a communication device, a video image of a property; enabling a selection of a plurality of features of interest associated with the property via the user interface; tracking a motion of the communication device as the communication device travels between adjacent features of interest in the plurality of features of interest; recording a location associated with each of the plurality of features of interest upon receiving the selection of each of the plurality of features of interest; determining a dimension for the property based on the motion of the communication device between the selection of each of the plurality of features of interest; and based on the determined dimension, generating a first instance of a sketch of the property.

Additionally, and although not described herein in any detail, it is understood that the interior scanning and sketching method may, where appropriate and desirable, include the method of scanning the interior corners of the property as interior features of interest using a process similar to that described above with respect to the scanning of the exterior corners of the property for generating a sketch of the exterior outline and shape of the property as described above.

Specific details were given in the description to provide a thorough understanding of the embodiments. However, it will be understood by one of ordinary skill in the art that the embodiments may be practiced without these specific details. For example, well-known circuits, processes, algorithms, structures, and techniques have been shown without unnecessary detail in order to avoid obscuring the embodiments.

What is claimed is:

1. A method for sketching a property, the method comprising:
presenting, via a user interface of a communication device, a video image of a property;
enabling a selection of a plurality of features of interest associated with the property via the user interface;
tracking a motion of the communication device as the communication device travels between adjacent features of interest in the plurality of features of interest;
recording a location associated with each of the plurality of features of interest upon receiving the selection of each of the plurality of features of interest;
determining a distance between at least two features of interest in the plurality of features of interest based on the motion of the communication device; and
based on the location associated with each of the plurality of features of interest and based on the distance between the at least two features of interest, generating a first instance of a sketch of the property.

2. The method of claim 1, further comprising:
providing the first instance of the sketch of the property to post-processing functionality that normalizes anomalies and/or reconciles features in the first instance of the sketch of the property;
receiving, from the post-processing functionality, a second instance of the sketch of the property, wherein the second instance of the sketch of the property is more accurate as compared to the first instance of the sketch of the property; and
presenting the second instance of the sketch of the property via the user interface of the communication device.

3. The method of claim 1, wherein at least one of the plurality of the features of interest comprises a corner of the property.

4. The method of claim 3, further comprising:
presenting, over the video image of the property, a feature indicator that is overlaid on the corner of the property.

5. The method of claim 4, wherein a position of the feature indicator is determined by at least one of a Light Detection and Ranging (LiDAR) sensor and photogrammetry.

6. The method of claim 4, wherein the feature indicator is overlaid on the corner of the property substantially simultaneous with receiving the selection of the corner.

7. The method of claim 1, further comprising:
referencing at least one of a compass and a motion sensor of the communication device to determine the distance between the at least two features of interest in the plurality of features of interest.

8. The method of claim 7, wherein the motion sensor comprises an inertial motion sensor.

9. The method of claim 1, further comprising:
referencing a Global Positioning System (GPS) of the communication device to determine the distance between the at least two features of interest in the plurality of features of interest.

10. The method of claim 1, further comprising providing the first instance of the sketch of the property to post-processing functionality that normalizes anomalies and/or reconciles the features in the first instance of the sketch of the property according to an order in which each of the plurality of features of interest are recorded.

11. The method of claim 1, wherein the plurality of features of interest comprises at least one of a corner and a perimeter wall.

12. The method of claim 1, further comprising providing the first instance of the sketch of the property to post-processing functionality that normalizes anomalies and/or reconciles the features in the first instance of the sketch of the property using at least one of an averaging function and a centering function.

13. A communication device, comprising:
a camera;
a user interface;
one or more sensors;
a processor coupled with the camera, the user interface, and the one or more processors; and
computer memory coupled with the processor, wherein the computer memory comprises instructions stored thereon that, when processed by the processor, enable the processor to:
present, via the user interface, a video image of a property captured by the camera;
enable a selection of a plurality of features of interest associated with the property via the user interface;
track a motion of the communication device using the one or more sensors as the communication device travels between adjacent features of interest in the plurality of features of interest;
record a location associated with each of the plurality of features of interest upon receiving the selection of each of the plurality of features of interest;
determine a distance between at least two features of interest in the plurality of features of interest based on the motion of the communication device; and
based on the location associated with each of the plurality of features of interest and based on the distance between the at least two features of interest, generate a first instance of a sketch of the property.

14. The communication device of claim 13, wherein the processor is further enabled to:
provide the first instance of the sketch of the property to post-processing functionality that normalizes anomalies and/or reconciles features in the first instance of the sketch of the property.

15. The communication device of claim 14, wherein the processor is further enabled to:
receive, from the post-processing functionality, a second instance of the sketch of the property, wherein the second instance of the sketch of the property is more accurate as compared to the first instance of the sketch of the property; and
present the second instance of the sketch of the property via the user interface.

16. The communication device of claim 15, wherein the at least one of the plurality of features of interest comprises a corner of the property and wherein the processor is further enabled to:
presenting, over the video image of the property, a feature indicator that is overlaid on the corner of the property.

17. The communication device of claim 16, wherein the one or more sensors comprises a Light Detection and Ranging (LiDAR) sensor and/or a light sensor.

18. The communication device of claim 16, wherein the feature indicator is overlaid on the corner of the property substantially simultaneous with receiving the selection of the corner.

19. The communication device of claim 14, wherein the one or more sensors comprises at least one of a compass and a motion sensor.

20. A method for sketching a property, the method comprising:
presenting, via a user interface of a communication device, a video image of a property;
enabling a selection of a plurality of features of interest associated with the property via the user interface;
tracking a motion of the communication device as the communication device travels between adjacent features of interest in the plurality of features of interest;
recording a location associated with each of the plurality of features of interest upon receiving the selection of each of the plurality of features of interest;
determining a dimension for the property based on the motion of the communication device between the selection of each of the plurality of features of interest; and
based on the determined dimension, generating a first instance of a sketch of the property.
